(19) United States
(12) Patent Application Publication
(10) Pub. No.: US 2020/0033122 A1
(43) Pub. Date: Jan. 30, 2020

(54) Pattern Evaluation Apparatus and Computer Program

(71) Applicant: Hitachi High-Technologies Corporation, Minato-ku, Tokyo (JP)

(72) Inventors: Yasutaka TOYODA, Tokyo (JP); Hiroyuki SHINDO, Tokyo (JP)

(21) Appl. No.: 16/337,694

(22) PCT Filed: Aug. 4, 2017
(86) PCT No.: PCT/JP2017/028403

§ 371 Date: Mar. 28, 2019

(30) Foreign Application Priority Data
Sep. 29, 2016 (JP) 2016-190511

(51) Int. Cl. G01B 15/04

(52) U.S. Cl. CPC G01B 15/04; H01J 37/28; G01B 2210/56

(57) ABSTRACT

The present invention is intended to provide a pattern evaluation apparatus and a computer program aimed at achieving defect inspection with high efficiency and high precision while allowing manufacturing variations that are dissimilar depending on the sites of a circuit. In order to achieve the above object, proposed are a computer program and an inspection system having a means of performing statistical processing of measurement data of a plurality of inspection target patterns having similar or same design pattern shape used for manufacturing the inspection target patterns, and performing adjustment of a defect determination threshold in accordance with a distribution state of measurement data.

### TECHNICAL FIELD

The present disclosure relates to a pattern evaluation apparatus and a computer program, and relates, in particular, to a pattern evaluation apparatus and a computer program that perform defect determination on the basis of comparison with reference data.

### BACKGROUND ART

In recent years, semiconductors have been further miniaturized and multilayered with further complication of logics, leading to situations having extreme difficulty in manufacturing such semiconductors. This results in an increase in occurrence of defects caused by the manufacturing process, leading to an increase in importance of accurately inspecting the defects.

A review scanning electron microscope (review SEM) that reviews defects on the basis of coordinate information of a defect detected by an optical inspection apparatus or the like, and a critical dimension-SEM (CD-SEM) that measures a pattern size on the basis of waveform information formed on the basis of the detected signal are used for detailed inspection and measurement of these defects. These SEM inspection apparatuses inspect patterns corresponding to inspection coordinates based on simulation of a semiconductor manufacturing process and patterns corresponding to inspection coordinates based on inspection results of an optical inspection apparatus or the like. Various inspection methods have been proposed. PTL 1 discloses a comparative inspection method of comparing design data using a reference pattern and a pattern obtained from an image, and further describes setting of pattern deformation tolerance in accordance with wiring attributes and whether the location includes complicates patterns. PTL 2 describes setting of tolerance values corresponding to sites of patterns in view of dissimilar importance of each of the pattern sites.

### CITATION LIST

### Patent Literature

PTL 1: JP 2004-163420 A (corresponding U.S. Pat. No. 8,045,785 B)

PTL 2: JP 2007-248087 A (corresponding to U.S. Pat. No. 8,019,161 B)

### SUMMARY OF INVENTION

### Technical Problem

The trend of miniaturization makes it difficult to precisely produce designed pattern shapes onto a wafer. In particular, curved sites such as corners and line ends and sites including patterns with high density are difficult to manufacture, and manufacturing variation suppressing operation is performed for these. It is, however, still difficult to uniformly suppress manufacturing variations of all patterns, and thus, adjustment is performed to the degree that would avoid affecting semiconductor device performance, so as to proceed to production.

Therefore, there is a demand for techniques for detecting a critical defect alone in consideration of such manufacturing variations, even at the inspection stage. While the pattern comparative inspection method as described in PTLs 1 and 2 can set the tolerance for determining whether a defect is present in accordance with the importance of the pattern sites, it is still difficult to set the tolerance that takes variations in view. In particular, although the variation gradually decreases through the suppression work, it is still difficult to separate a shape error to be defined as a defect changing with the stage of the suppression work from a variation, and thus, it is very difficult to set appropriate tolerances for all circuit sites constituting a semiconductor device.

The following is a proposed pattern evaluation apparatus and a computer program aimed at achieving defect inspection with high efficiency and high precision while allowing manufacturing variations that are dissimilar depending on the pattern sites.

### Solution to Problem

In order to achieve the above aim, proposed are a pattern evaluation apparatus and a computer program, capable of adjusting defect determination threshold (tolerance value) in accordance with a distribution state of measurement data of a plurality of inspection target patterns having similar or same design pattern shape used for manufacturing the inspection target patterns.

### Advantageous Effects of Invention

According to the above configuration, a threshold (tolerance) for detecting a defect from measurement values of a plurality of patterns having the same or similar design information is generated, making it possible to execute inspection to detect a critical defect alone with high precision and high efficiency while allowing manufacturing variations that are dissimilar depending on the sites of the patterns.

### BRIEF DESCRIPTION OF DRAWINGS

FIG. 1 is a flowchart illustrating a procedure for determining an appropriate defect determination threshold at a site of a circuit in consideration of manufacturing variations.

FIG. 2 is a diagram illustrating a configuration of a semiconductor inspection system.

FIG. 3 is a view illustrating an inspection target pattern.

FIG. 4 is a diagram illustrating a design pattern.

FIG. 5 is a flowchart illustrating a procedure for pattern ID determination.

FIG. 6 is a view illustrating a difference in measuring method depending on patterns.

FIG. 7 is a chart illustrating a measurement reference table.

FIG. 8 is a graph illustrating a histogram of measurement data.

FIG. 9 is a diagram illustrating a relationship between a histogram of measurement data and a defect determination threshold.

FIG. 10 is a flowchart illustrating a procedure for generating a defect determination threshold.

FIG. 11 is a flowchart illustrating a defect determination procedure.

FIG. 12 is a flowchart illustrating a systematic defect determination procedure.

FIG. 13 is a diagram illustrating systematic defects.

FIG. 14 is a diagram of a GUI displaying inspection parameter instructions and inspection results.

FIG. 15 is a diagram illustrating an example of GUI displaying inspection results.

FIG. 16 is a diagram illustrating an outline of an inspection system.

FIG. 17 is a flowchart illustrating a procedure of contour detection.

FIG. 18 is a diagram illustrating an outline of contour extraction.

FIG. 19 is a flowchart illustrating an inspection procedure.

FIG. 20 is a diagram illustrating contour points of a wiring end.

FIG. 21 is a view illustrating an example of shape distortion of a wiring end.

FIG. 22 is a flowchart illustrating a calculation procedure of a curvature statistic.

### DESCRIPTION OF EMBODIMENTS

Exemplary embodiments described below mainly relates to: a pattern evaluation apparatus that performs evaluation of pattern measurement and inspection, etc. using design information and a photographed image of an inspection pattern; a computer program that causes an arithmetic processing device or the like to execute the evaluation; and a readable storage medium storing the computer program.

First, an inspection operator defines a design pattern corresponding to the inspection pattern. Next, the design pattern and the inspection pattern are superimposed with each other. Superimposition uses manual adjustment or an automatic adjustment method using pattern matching. Next, a measurement reference table is generated with reference to the shape of the design pattern, and measurement values and inspection coordinates are registered onto the generated table. The measurement reference table is a database onto which measurement values and inspection coordinates of the inspection target pattern are to be registered. Inspection target patterns having an equivalent ideal shape can be grouped and registered for each of patterns, and a target group is determined with reference to a design pattern used for manufacturing the inspection pattern, so as to register the measurement values and inspection coordinates.

In registration of the measurement reference table, measurement values and inspection coordinates are registered to a target group in a case where the target group already exists, or a new group is created and the measurement values and inspection coordinates are registered to the newly created group in a case where no target group exists.

The above procedure is executed for each of inspection points to form groups of patterns having the same ideal shape in the measurement reference table, leading to accumulation of the measurement values of the inspection pattern and the corresponding inspection coordinates in each of the groups. The average and standard deviation of the measurement values of each of the groups are calculated after a certain degree of accumulation of measurement values of each of the groups, or after the inspection, so as to determine a threshold in consideration of manufacturing variations. For example, a threshold is generated for determining a pattern of measurement values outside the measurement value range of (measurement value−standard deviation) to (average value+standard deviation), as a defect. Finally, the threshold generated for each of groups is compared with the measurement value, so as to detect the defect. This leads to implementation of defect inspection that allows manufacturing variations that are dissimilar depending on the sites of the circuit. More details will be described in the following exemplary embodiments.

### [First Exemplary Embodiment]

Specific examples of a pattern inspection method and a semiconductor inspection system will be described below with reference to the drawings.

FIG. 2 is a diagram illustrating an outline of a semiconductor inspection system. The semiconductor inspection system includes: a scanning electron microscope 201 (hereinafter referred to as an SEM) for obtaining image data of a circuit pattern; and a control unit 214 for inspecting the circuit pattern by analysis of image data. The SEM 201 emits an electron beam 202 onto a sample 203 such as a wafer on which an electronic device is manufactured, captures electrons emitted from the sample 203 by using a secondary electron detector 204 and backscattered electron detectors 205 and 206, and use an A/D converter 207 to convert the electron into a digital signal. The digital signal is input to the control unit 214 and stored in a memory 208, and undergoes image processing according to the purpose on a CPU 209 or image processing hardware devices 210 such as ASIC and FPGA, so as to inspect the circuit pattern.

Furthermore, the control unit 214 is connected to a display 211 having an input means, and has a function such as Graphical User Interface (GUI) for displaying images, inspection results or the like to the user. It is also possible to assign some or all of the control in the control unit 214 to a CPU, an electronic computer or the like having a memory capable of storing images so as to perform processing and control. The control unit 214 is further connected, via a network, a bus, or the like, to an imaging recipe creation device 212 that creates an imaging recipe including coordinates of the electronic device needed for inspection, a pattern matching template used for inspection positioning, and photographing conditions, manually or by using design data 213 of the electronic device.

FIG. 16 is a diagram illustrating an arithmetic processing device built in the control unit 214 in more detail. The semiconductor inspection system illustrated in FIG. 16 includes: a scanning electron microscope main body 1601; a control device 1604 that controls the scanning electron microscope main body; an arithmetic processing device 1605 that transmits a control signal to the control device 1604 on the basis of a predetermined operation program (recipe) and that executes shape evaluation of a pattern from signals (secondary electrons, backscattered electrons, etc.) obtained by scanning electron microscope; a design data storage medium 1616 that stores design data of a semiconductor device; a design device 1618 that performs design data creation and design data correction using simulation; and an input/output device 1617 for inputting a predetermined semiconductor evaluation condition and outputting a measurement result and a defect determination result.

The arithmetic processing device 1605 functions as a data processing device for determining the normality/defect of the pattern from the obtained image. The control device 1604 controls a sample stage and a deflector in the scanning electron microscope main body 1601 on the basis of an instruction from a recipe execution unit 1606, and executes positioning of a scanning region (view field) to a desired position. The control device 1604 supplies a scanning signal corresponding to the set magnification and the view field size to the scanning deflector 1602. The scanning deflector 1602 changes the magnification (magnification) of the view field to a desired size according to the supplied signal.

An image processing unit 1607 included in the arithmetic processing device 1605 processes an image obtained by arranging detection signals from a detector 1603 in synchronization with the scanning performed by the scanning deflector 1602. The arithmetic processing device 1605 incorporates a memory 1609 to store necessary operation programs, image data, observed feature data, or the like.

The image processing unit 1607 further includes: a matching processing unit 1610 for specifying an evaluation target in an image using a template stored in advance; a contour extraction unit 1611 that extracts a contour from image data as described below; a measurement reference table generation unit 1612 that analyzes a design pattern corresponding to an inspection position and generates a measurement reference table; a measurement unit 1613 that performs measurement of the dimension of the inspection pattern, shape quantification, and calculation of comparison amount from the reference pattern; a defect determination threshold generation unit 1614 that generates a threshold for determining a defect from a statistic of the measurement value for each of pattern groups; and a defect determination unit 1615 that compares the measurement value with the threshold for each of pattern groups to determine normality/defect of the pattern.

Electrons emitted from the sample are captured by the detector 1603 and converted into digital signals by an A/D converter incorporated in the control device 1604. Image processing according to the purpose is performed by the CPU or image processing hardware devices such as ASIC and FPGA built in the image processing unit 1607.

The arithmetic processing device 1605 is connected to the input/output device 1617, and has a function such as a Graphical User Interface (GUI) for displaying an image, an inspection result or the like to the operator on a display device provided in the input/output device 1617.

Furthermore, the input/output device 1617 also functions as an imaging recipe creation device that creates an imaging recipe including coordinates of the electronic device needed for measurement and inspection, etc., a pattern matching template used for positioning, and photographing conditions, manually or by using design data stored in the design data storage medium 1616 of the electronic device.

The input/output device 1617 includes a template creation unit that cuts out a portion of a diagram image formed on the basis of design data and provides it as a template, and the created template is registered to the memory 1609 as a template for template matching performed by the matching processing unit 1610. The template matching is a method of specifying a portion achieving template match with a captured image as an alignment target on the basis of matching degree determination using a normalized correlation method or the like. The matching processing unit 1610 specifies a desired position of the captured image on the basis of the matching degree determination. While the present exemplary embodiment expresses the degree of matching between a template and an image by the word “matching degree” or “similarity”, the words are the same in terms of an index indicating the degree of matching between the template and the image. In addition, non-matching degree and dissimilarity are also aspects of the degree of matching and similarity.

The image processing unit 1607 incorporates an image integration unit 1608 that integrates the signals obtained by the SEM to form an integrated image. In the case where there is a plurality of detectors 1603 for capturing electrons, an image combining a plurality of signals obtained by a plurality of detectors is created. This configuration makes it possible to generate an image according to the purpose of inspection. Moreover, by integrating a plurality of images obtained by one detector, it is possible to generate an image that suppresses the noise included in each of the images.

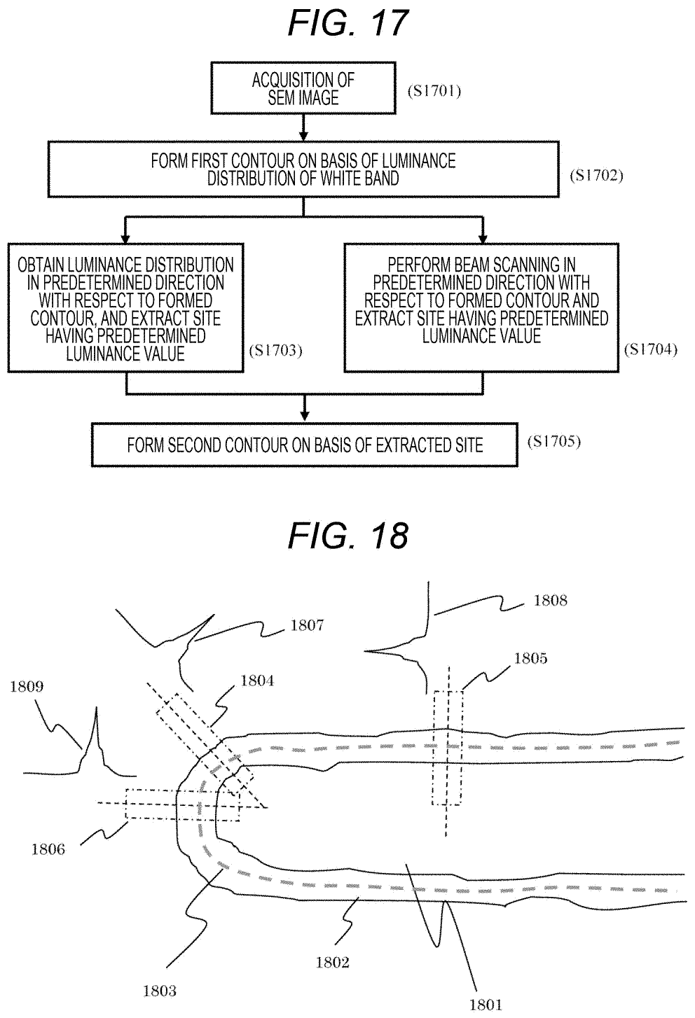

The contour extraction unit 1611 extracts a contour from image data in accordance with a flowchart illustrated in FIG. 17, for example. FIG. 18 is a diagram illustrating an outline of the contour extraction.

First, an SEM image is obtained (step 1701). Next, a first contour is formed on the basis of luminance distribution of a white band (step 1702). Here, edge detection is performed using a white band method or the like. Next, luminance distribution is obtained in a predetermined direction with respect to the formed first contour, so as to extract a portion having a predetermined luminance value (step 1703). Here, the predetermined direction is preferably a direction perpendicular to the first contour. As illustrated in FIG. 18, a first contour 1803 is formed on the basis of a white band 1802 of a line pattern 1801, and luminance distribution acquisition regions (1804 to 1806) are set for the first contour 1803, so as to obtain luminance distribution (1807 to 1809) in the direction perpendicular to the first contour.

The first contour 1803 indicates an approximate shape of the pattern with a coarse contour, and in order to form a contour with higher precision with reference to the contour, luminance distribution is detected on the basis of the contour. By detecting the luminance distribution in the direction perpendicular to the contour, it is possible to reduce a peak width of a profile, resulting in achievement of detection of an accurate peak position, or the like. For example, by joining peak top positions, it is possible to form high-precision contours (second contours) (step 1705). Alternatively, a predetermined brightness portions may be joined to form a contour instead of detecting the peak tops.

Furthermore, in order to create the second contour, electron beam scanning can be applied in a direction perpendicular to the first contour 1803 to form a profile (step 1704), so as to form the second contour.

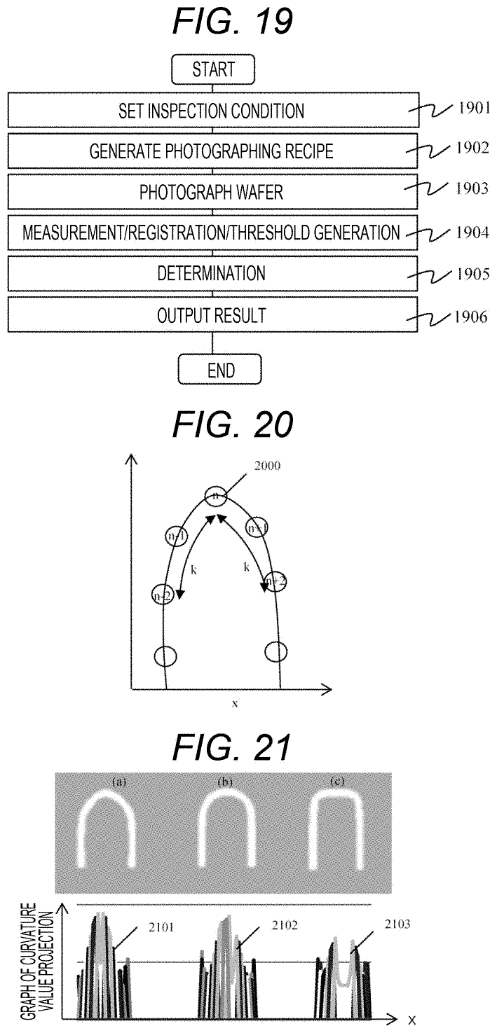

FIG. 19 is a flowchart illustrating a pattern inspection procedure. The present exemplary embodiment will describe an example of applying the inspection method of the present invention to the inspection of defect potential sites on a wafer, which are preliminarily specified in a visual inspection device, evaluation of semiconductor process simulation, or the like. Note that a defect potential site is a site where occurrence of defect is predicted.

First, an operator sets inspection conditions for photographing and inspecting a circuit pattern on a wafer using the recipe creation device 212 (step 1901). The inspection conditions include photographing magnification of the SEM 201 and coordinates of a circuit pattern as inspection target (hereinafter referred to as inspection coordinates). Next, a photographing recipe is generated on the basis of the set inspection condition (step 1902). The photographing recipe is data for controlling the SEM 201, and defines inspection conditions set by an inspection operator and templates for specifying an inspection position from the photographed image. Next, on the basis of the recipe, a circuit pattern is photographed by the SEM 201, pattern matching is performed by using a template for positioning, and inspection points in the photographed image are specified (step 1903). Next, a measurement suitable for the target pattern is performed on the basis of the design pattern, measurement data and inspection coordinates are registered in a matching pattern library. After accumulation of measurement values of the pattern library to a certain amount, a threshold for determining a defect is generated on the basis of the statistics of the measurement values (step 1904). Next, the defect is determined by comparison with the measurement value (step 1905). Finally, a result is output to the memory 208 or the display 211 (step 1906).

Hereinafter, details of the procedure (step 1904) from pattern measurement to the generation of the defect determination threshold and the procedure (step 1905) of defect determination will be described with reference to a specific example.

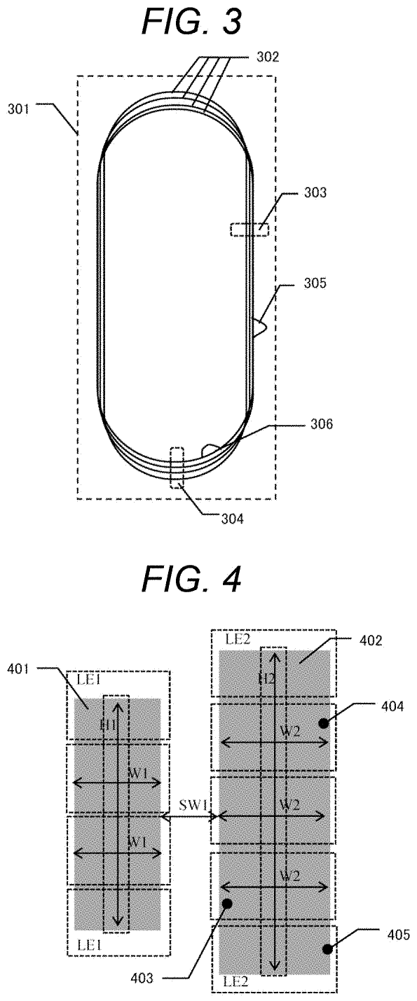

FIG. 3 is a view of four inspection patterns 302 having different manufacturing points on the wafer being overlapped with each other. All of these four inspection patterns 302 have been manufactured by a design pattern 301 having the identical shape. Miniaturization of patterns makes it difficult to perform manufacturing these, and the manufactured patterns have various shapes as indicated by broken line areas 303 and 304. Additionally, the magnitude of the variation varies depending on the shape of the pattern and the surrounding pattern. These variations are suppressed to such an extent to avoid affecting the performance of the semiconductor device during the development stage of the manufacturing process, although extremely difficult to be completely suppressed. For this reason, particularly in an inspection as substantially mass production, there is a need to provide a measure of excluding this manufacturing variation from defects in the determination. On the other hand, deformation exceeding manufacturing variations made by many pattern shapes as in 305 would be highly likely to be defective, so as to be an object to be detected by inspection.

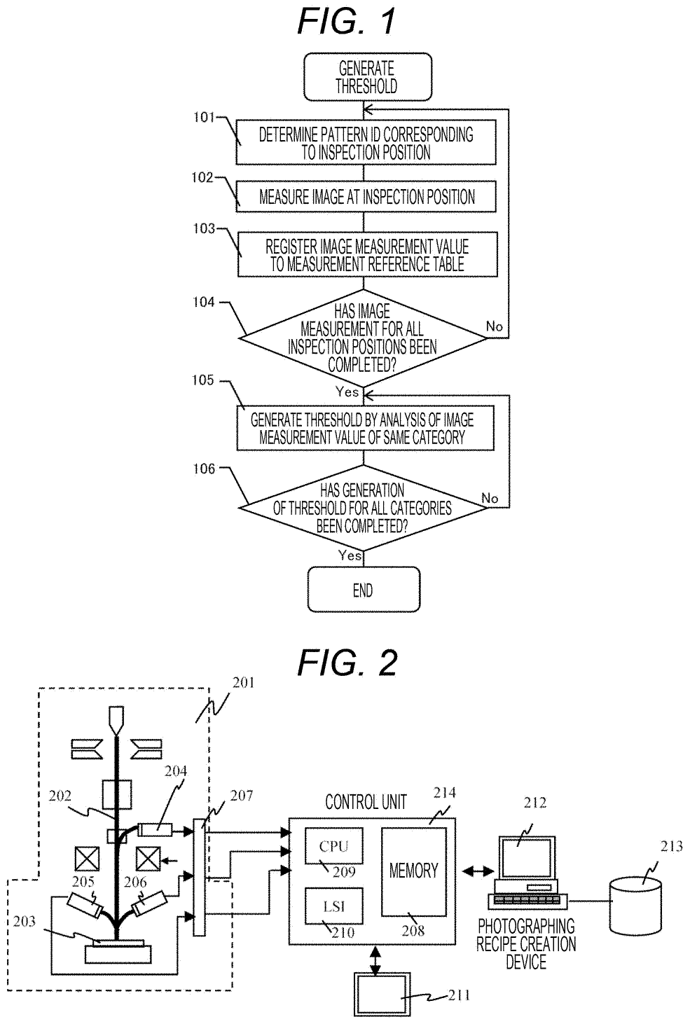

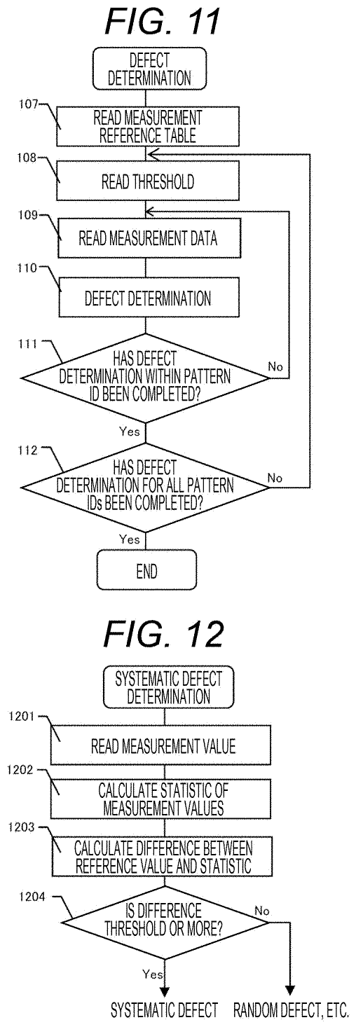

In order to detect defects while allowing different manufacturing variations depending on sites of the pattern, an inspection is performed in the procedure illustrated in FIGS. 1 and 11, to be executed by the image processing unit 1607. FIG. 1 is a flowchart related to generation of a threshold for defect determination from pattern measurement.

First, a design pattern corresponding to inspection coordinates is analyzed, and a pattern ID corresponding to the inspection coordinates is determined (step 101).

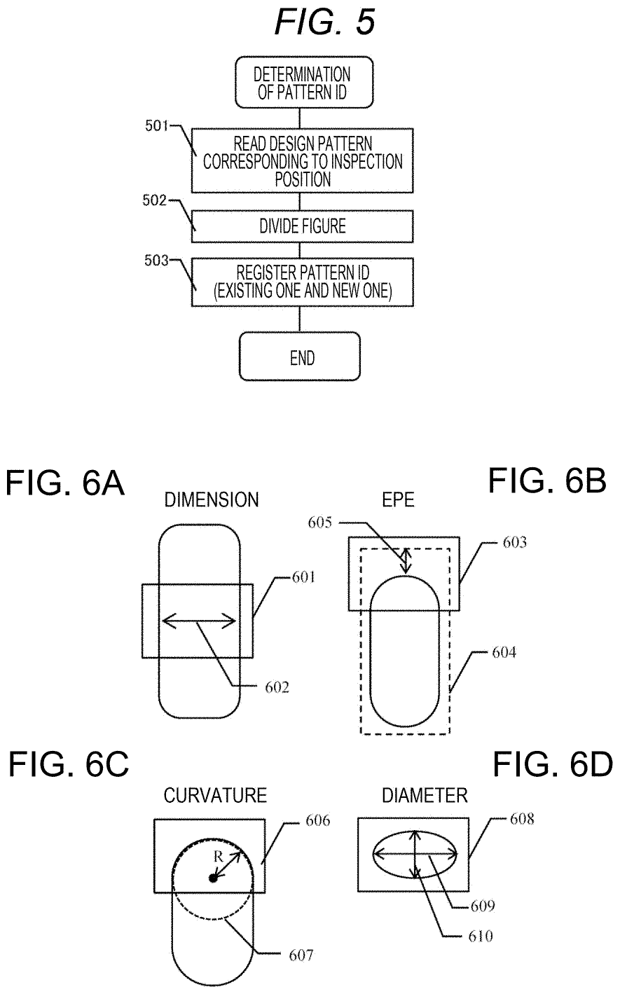

Pattern ID is provided to identify the measurement value and the inspection coordinates of the pattern manufactured so as to have a same design value, and is determined by the procedure illustrated in FIG. 5. First, a design pattern corresponding to inspection coordinates is read (step 501). Next, the design pattern is divided into measurement unit areas (step 502). The measurement unit area is set as a unit of regions for generating measurement data for evaluating defects of inspection coordinates. Next, a pattern ID is set in all the measurement unit areas including the inspection coordinates, and registered in the memory as data from which the pattern ID can be referred to from the inspection coordinates (step 503). This will be specifically described below with reference to FIG. 4.

FIG. 4 is a view illustrating an example of a design pattern including inspection coordinates 403, 404, and 405 and an example of a measurement unit area (broken line region). In the figure, each of W1, W2, H1, H2, SW1, LE1, and LE2 represents a pattern ID. The same ID (identification information) is set in the measurement unit area having the same design pattern shape. For example, since the design patterns of the measurement unit areas including the inspection coordinates 403 and 404 have the same shape, the same pattern ID is set for these areas. Furthermore, it is also possible to define a measurement method suitable for the pattern at the time of setting the pattern ID. FIG. 6 illustrates an appropriate measurement method for each of sites of patterns. FIG. 6(a) illustrates a case where a measurement unit area 601 is set in a center portion of the wiring pattern, and in order to measure the contraction of the pattern, a method for measuring a pattern dimension 602 is defined as the pattern ID corresponding to this area. FIG. 6(b) illustrates a case where a measurement unit area 603 is set at the wiring end, and in order to measure a withdrawal amount of the wiring end, a method for measuring a difference (an edge placement error (EPE)) 605 between a design pattern 604 and this pattern is defined as the pattern ID corresponding to this area. The EPE is a deviation between corresponding points in a reference pattern (reference data) generated from design data or the like and contour data extracted from an SEM image. Obtaining the EPE enables evaluation of divergence between the actual pattern shape and an ideal pattern shape.

In addition, since it is also necessary to detect a distortion defect of the shape at the wiring end, a method for measuring the curvature of the pattern at the wiring end is also defined as illustrated in FIG. 6(c).

FIG. 21 illustrates an example of the shape distortion at the wiring end. FIGS. 21(a) and 21(b) illustrate wiring ends with distorted shapes while FIG. 21(c) illustrates a wiring end with a normal shape. When the shape of the wiring end is distorted as illustrated in FIGS. 21(a) and 21(b) in a case where a via connecting the wiring and the wiring of the upper and lower layers exists at the position of the wiring end, the connection area of the via would be reduced, affecting the performance of the semiconductor device. For this reason, accurately quantifying the shape distortion amount at the wiring end would be a necessity. One example of quantifying shape distortion at the wiring end will be described below.

FIG. 20 illustrates a set of contour points 2000 constituting the contour of the pattern of the wiring end portion. The curvature is calculated by using Formula (1) for each of these contour points.

$$Curvature ( k ) = \frac{{d}^{2} y / {d}^{2} x}{{\{ 1 + {( dy / dx )}^{2} \}}^{3 / 2}} \\ \frac{{d}^{2} y}{{dx}^{2}} = {d}_{+} - {d}_{-} , \frac{dy}{dx} = {d}_{+ -} \\ {d}_{-} = \frac{1}{k} {\sum }_{i = k + 1}^{0} \frac{{y}_{i - 1} - {y}_{i}}{{x}_{i - 1} - {x}_{i}} \\ {d}_{+} = \frac{1}{k} {\sum }_{i = 0}^{k - 1} \frac{{y}_{i} - {y}_{i + 1}}{{x}_{i} - {x}_{i + 1}} \\ {d}_{+ -} = \frac{1}{k} {\sum }_{i = k / 2}^{k / 2} \frac{{y}_{i - 1} - {y}_{i}}{{x}_{i - 1} - {x}_{i}} \qquad [ Mathematical Formula 1 ]$$

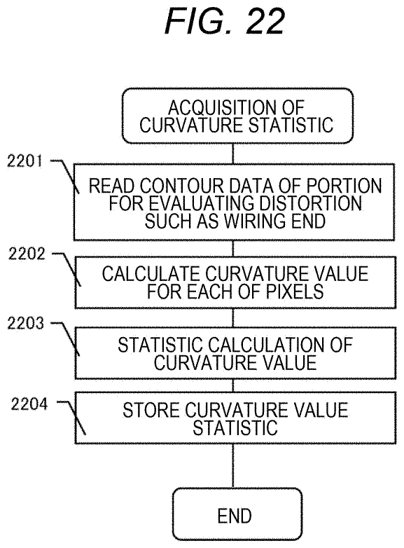

In FIG. 21, signs 2101 to 2103 indicate graphs obtained by projecting curvature values of the contour points in (a), (b) and (c) of FIG. 21, onto the X coordinate. It can be observed that the greater the distortion at the wiring end is, the higher the curvature value is. Note that, in a case where a representative value of one contour is adopted as a curvature value, shape distortion might not be accurately reflected in the curvature value due to an influence of a noise component contained in the contour. To avoid this, the curvature statistic is obtained by the procedure as illustrated in FIG. 22 to be applied as the measurement data of the curved site such as the wiring end. Hereinafter, a generation procedure of the curvature statistic will be described. First, contour data of the pattern ID for evaluating the distortion of the wiring end or the like is read (step 2201). Next, the curvature value for each of contour points is measured using Formula 1 or the like (step 2202). Next, statistical calculation of curvatures of a plurality of contour points is performed to calculate curvature statistic (step 2203). The curvature statistic is stores in the measurement reference table as a measurement value of the last pattern ID (step 2204). The statistical calculation of the curvature value is, for example, calculation of an average value, standard deviation, a maximum value, an average value of the above-described n curvature values arranged in descending order from the maximum value, or the like.

FIG. 6(d) illustrates a case where a measurement unit area 608 is set in a hole pattern, and a method of measuring the area of areas surrounded by a major axis 609, a minor axis 610, or the contour is defined for the pattern ID corresponding to this area. Furthermore, by analyzing the shape of the design pattern in the measurement unit area, it is also possible to obtain a target design value.

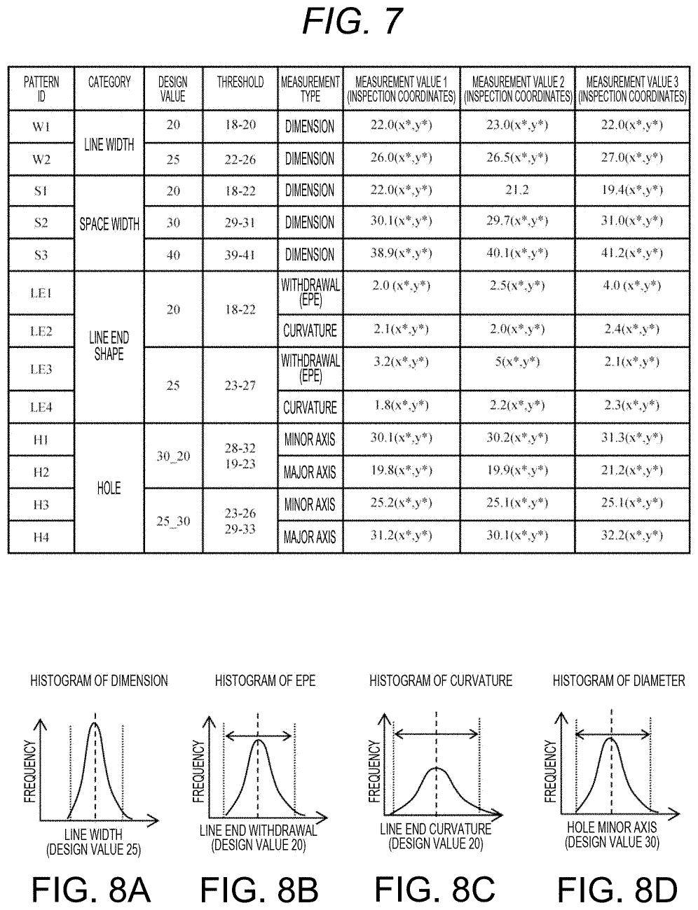

The correlation between the pattern ID, the design value, the inspection coordinates, and the measurement methods as described above is stored in the memory as a measurement reference table as illustrated in FIG. 7. The reference table illustrated in FIG. 7 can store a plurality of measurement values for each of features of the shape features of the pattern site as a measurement target (for example, for each of combinations of category and design value).

Next, image measurement of an inspection coordinate position is performed (step 102). A specific example will be described below. First, a measurement reference table is used to determine a measurement type corresponding to inspection coordinates, and then, measurement data obtained by image analysis is generated on the basis of the measurement method. In the case of measuring the line width and the space width, the dimension of the pattern corresponding to the inspection coordinates is measured. In the case of measuring the line end shape, shape error (EPE) from the design pattern and the curvature value are measured. In the case of measuring a hole, the area of the area surrounded by the minor axis, the major axis, and the contour is measured.

Next, the image measurement value is registered to the measurement reference table of the corresponding pattern ID (step 103). The procedures of the above steps 101 to 103 are performed for all the inspection coordinates (step 104).

After completion of all inspections, a threshold for defect determination is generated for all pattern IDs (step 105). In recent years, the number of inspection targets ranges from several thousands to several tens of thousands. Still, since variations of pattern shapes are not too many, it is possible to accumulate sufficient measurement data for evaluating the variations in shape of each of pattern ID after completion of the inspection. FIG. 8 illustrates histograms of measurement data (horizontal axis: measurement value, vertical axis: frequency) of measurement data by each of measurement methods. The distribution state of such measurement data is analyzed to generate a threshold for defect determination.

A procedure for generating a threshold for defect determination will be described with reference to the flowchart of FIG. 10.

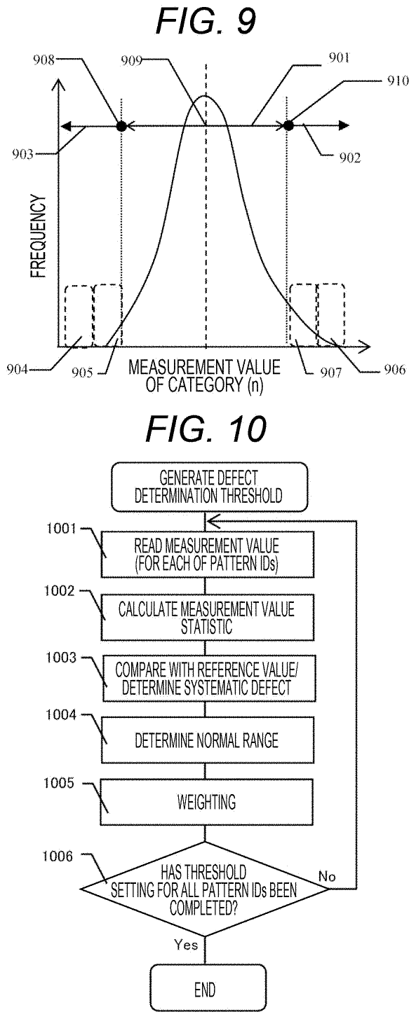

FIG. 9 is a diagram illustrating a histogram of measurement values of a certain pattern ID, in which the horizontal axis indicates the measurement value and the vertical axis indicates the frequency. Since the pattern ID is set for each of measurement unit areas having an equivalent design pattern, the measurement value=design value ideally. The distribution, however, takes this form due to manufacturing variation. First, all measurement data registered in one pattern ID are read from the measurement reference table (step 1001). Next, the statistic of the measurement values is calculated (step 1002). The statistic of the measured value is the average value or the standard deviation value of all the measurement values. The example of FIG. 9 illustrates points of an average value 909, (average value−standard deviation) 908, and (average value+standard deviation) 910. This average value is the average value in the current manufacturing process, and the more deviating from the average value, the higher the possibility of defect.

Note that in a case where the defect is a systematic defect such as mask defect, the same defect is generated in each of patterns, producing the average value of the measurement data largely diverging from the design value. For this reason, prior to threshold generation, the degree of divergence from this design value is estimated to determine the presence or absence of a systematic defect (step 1003). A specific systematic defect determination procedure is illustrated in FIG. 12. First, all measurement values of the same pattern ID are read (step 1201). Next, a statistic such as an average value and a standard deviation of measurement values is calculated (step 1202). Next, a difference between the reference statistic such as the design value and the predicted value and the statistic from the measurement data is calculated (step 1203).

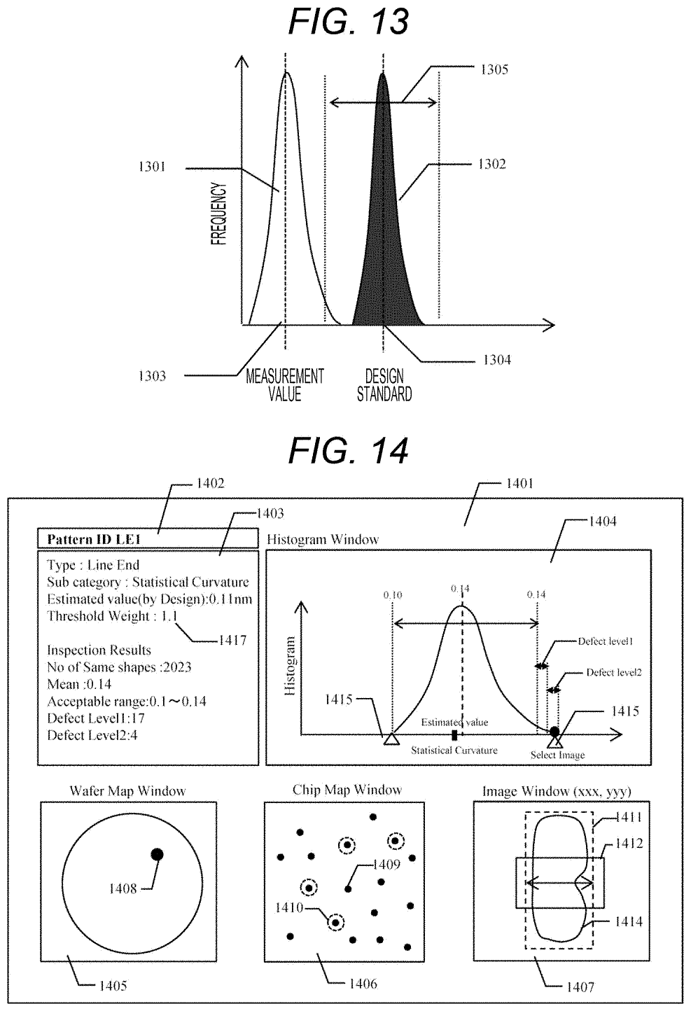

FIG. 13 is a diagram illustrating a histogram 1301 of measurement data and a histogram 1302 of measurement predicted value obtained by simulation of the manufacturing process. The average value 1303 of the measurement data greatly diverges from the design standard value 1304 based on the process simulation. Such a divergence is specified by comparing the difference value of the statistic amount with a predetermined threshold and determined as a systematic defect (step 1204). After systematic defect determination, a threshold for determining the section of (average value−standard deviation) to (average value+standard deviation) as a normal measurement value is generated (step 1004). It is also possible to generate a threshold weighted to the above range by the pattern ID (step 1005). Steps 1001 to 1005 are executed for each of target pattern ID, and an obtained defect determination threshold is registered in the memory. It is also possible to provide certain sections 905 and 907 within the above threshold range and to set a threshold such that the pattern corresponding to that section is to be identified as a defect potential site and the other sections 904 and 906 as defect sites. Such threshold generation is performed for all pattern IDs and registered in the measurement reference table (step 106).

Note that a statistical value totaled on the basis of the ID are past data, and thus the threshold obtained on the basis of this statistical value might be too low as a target value of the future work of suppressing the manufacturing variation. Accordingly, a tolerance range may be set by multiplying by a predetermined coefficient so as to be narrower than the range (average value−standard deviation) to (average value+standard deviation).

Next, a defect determination procedure will be described with reference to the flowchart of FIG. 11. First, the measurement reference table is read (step 107). Next, a threshold of the pattern ID is read out from the measurement reference table (step 108). Measurement values of the same pattern ID are sequentially read (step 109). By comparison with the threshold, a defect is determined and registered in the memory together with inspection coordinates (step 110). The above steps 108 to 110 are performed on all measurement data in the pattern ID (step 111). This procedure is executed for measurement data of all pattern IDs in the measurement reference table (step 112).

The above configuration is used to implement defect inspection that allows manufacturing variations that are dissimilar depending on the sites of the circuit.

Next, a GUI effective for defect inspection will be described. This GUI makes it possible to allow the user to set inspection parameters, or allow the user to confirm the defect inspection result. FIG. 14 illustrates an example of GUI. A GUI 1401 includes: a window 1402 illustrating a pattern ID, a window 1403 illustrating its detailed information; a window 1404 illustrating a histogram of measurement values corresponding to the pattern ID; a window 1405 visualizing inspection coordinates 1408 on the wafer; coordinates 1409 determined as a defect within a chip or within a shot; a window 1406 illustrating inspection coordinates 1410 determined to be a potential defect; and a window 1407 illustrating an inspection target pattern 1414, a design pattern 1411, and a measurement unit area 1412. The GUI 1401 performs display information on a display on the basis of the inspection coordinates, a photographed image of the pattern, the design pattern, the measurement reference table, and the defect determination result. The GUI program is started as an execution program of the CPU. In addition, items such as a weight 1417 based on a threshold for defect determination, a slider 1415 for adjusting the threshold, and switching of the pattern ID can be designated by the user.

With utilization of such a GUI, the user can easily confirm the defect determination result.

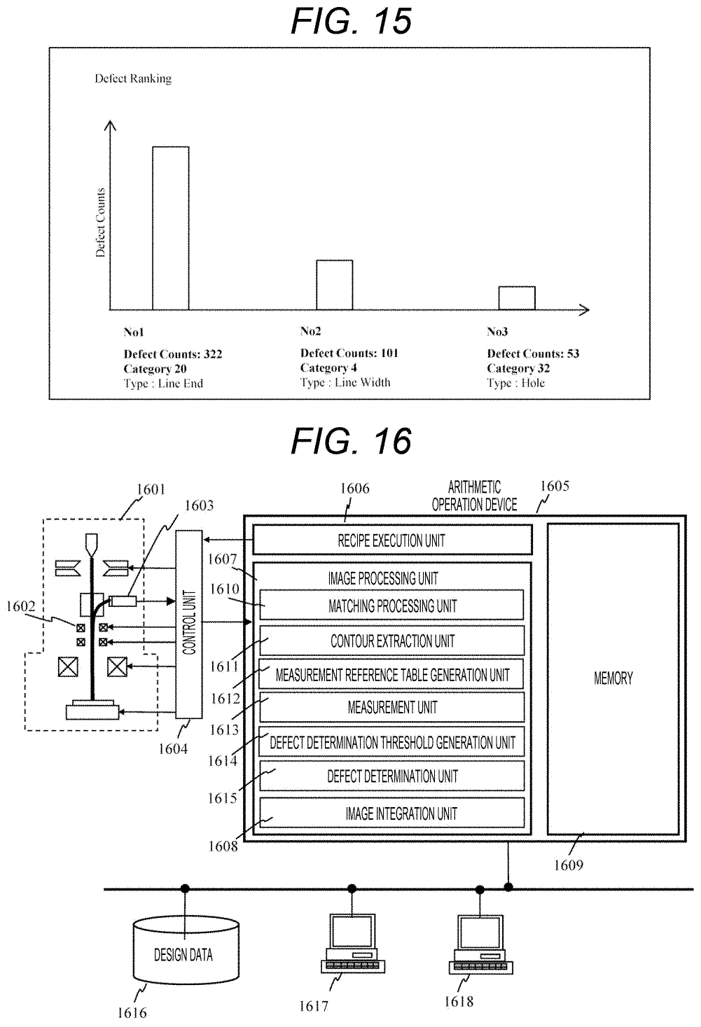

Furthermore, the pattern ID can be displayed as a defect ranking in the GUI in order of the number determined as defect (defect counts) as illustrated in FIG. 15, enabling the user to easily confirm the critical defect site.

The above-described pattern defect determination or the like may be executed by dedicated hardware or it is allowable to control a general-purpose computer to execute the above-described processing.

### REFERENCE SIGNS LIST

201 SEM
202 electron beam
203 sample
204 secondary electron detector
205 backscattered electron detector 1
206 backscattered electron detector 2
207 A/D converter
208 memory
209 CPU
210 hardware
211 display means
212 recipe generation system
213 design data
214 control unit
301 design pattern
302 plurality of inspection target patterns
303 manufacturing variation 1
304 manufacturing variation 2
305 defect 1
306 defect 2
401 design pattern 1
402 design pattern 2
403 inspection coordinates 1
404 inspection coordinates 2
405 inspection coordinates 3
601 measurement unit area
602 dimension measurement site
603 measurement unit area
604 design pattern
605 amount of error between design pattern and inspection pattern
606 measurement unit area
607 circle fitted to pattern
608 measurement unit area
609 major axis of hole
610 minor axis of hole
901 within threshold (normal)
902 out-of-threshold (defect)
903 out-of-threshold (defect)
904 defect area (lower Limit)
905 defect potential area (lower limit)
906 defect area (upper Limit)
907 defect potential area (upper limit)
908 defect determination threshold (lower limit)
909 average value of measurement data
910 defect determination threshold (upper limit)
1301 histogram of measurement data
1302 estimated histogram by process simulation, etc.
1303 average value of measurement data
1304 average value of estimated histogram
1305 distribution range of estimated histogram
1401 GUI screen
1402 pattern ID window
1403 pattern ID detailed data window
1404 measurement data histogram window
1405 wafer map window
1406 chip map window
1407 inspection pattern window
1601 scanning electron microscope main body
1602 scanning deflector
1603 detector
1604 control device
1605 arithmetic processing device
1606 recipe execution unit
1607 image processing unit
1608 image integration unit
1609 memory
1610 matching processing unit
1611 contour extraction unit
1612 measurement reference table generation unit
1613 measurement unit
1614 defect determination threshold generation unit
1615 defect determination unit
1616 design data storage
1617 Input/output device
1618 design device
1801 line pattern
1802 white band
1803 first contour
1804 to 1806 Luminance distribution acquisition region
1807 to 1809 luminance distribution in direction perpendicular to first contour

1. A pattern evaluation apparatus comprising an arithmetic processing device that detects a defect of a pattern on the basis of a comparison between a measurement value of the pattern and a predetermined threshold,
the apparatus further comprising a storage medium that stores the measurement value of the pattern,
wherein the arithmetic processing device obtains an index value indicating variations of a plurality of measurement values of a same pattern on design data stored in the storage medium, and sets the threshold in accordance with the index value.

2. The pattern evaluation apparatus according to claim 1,
wherein the arithmetic processing device obtains a statistical value of the plurality of measurement values of the same pattern on the design data, and obtains the index value from the statistical value.

3. The pattern evaluation apparatus according to claim 2,
wherein the arithmetic processing device sets the threshold on the basis of standard deviation of the index value.

4. The pattern evaluation apparatus according to claim 1,
wherein the arithmetic processing device uses the design data to classify the plurality of measurement values for each of types of sites of the pattern.

5. The pattern evaluation apparatus according to claim 1,
wherein the arithmetic processing device assigns identification information corresponding to the site of the pattern to the measurement value, and obtains the index value for the measurement value having the same identification information.

6. The pattern evaluation apparatus according to claim 1,
wherein the measurement value is at least one of dimension, a difference between reference data and contour data, curvature of a portion of the pattern, a major axis of a circular pattern, a minor axis of a circular pattern, and an area of a circular pattern.

7. The pattern evaluation apparatus according to claim 6,
wherein the curvature is obtained by statistical calculation of curvatures of a plurality of sites constituting the pattern.

8. The pattern evaluation apparatus according to claim 1,
wherein the arithmetic processing device classifies the pattern into a site including a top of the pattern and a site not including the top of the pattern, and obtains the variation in units of the classified sites.

9. The pattern evaluation apparatus according to claim 1,
wherein the arithmetic processing device divides an edge of the pattern into a plurality of regions, and performs statistical processing of the measurement values in units of the divided regions.

10. The pattern evaluation apparatus according to claim 1,
wherein, in a case where two or more peaks exist in a histogram of the measurement value, the arithmetic processing device defines a measurement value belonging to the peak including a measurement value relatively diverging from a design standard out of the two or more peaks, as a systematic defect.

11. A computer program causing a computer to execute comparison operation of a measurement value of a pattern with a predetermined threshold to detect a defect in the pattern,
the program causing the computer to obtain an index value indicating variations of a plurality of measurement values of a same pattern on design data stored in a storage medium and causing the computer to set the threshold in accordance with the index value.
